(19) United States
(12) Patent Application Publication
(10) Pub. No.: US 2024/0258765 A1
(43) Pub. Date: Aug. 1, 2024

(54) LASER DIODE DEVICE AND PRODUCTION METHOD

(71) Applicant: Robert Bosch GmbH, Stuttgart (DE)

(72) Inventor: Stefan Pinter, Reutlingen (DE)

(21) Appl. No.: 18/040,407

(22) PCT Filed: Sep. 28, 2021
(86) PCT No.: PCT/EP2021/076620

§ 371 Date: Feb. 2, 2023

(30) Foreign Application Priority Data
Nov. 30, 2020 (DE) 10 2020 215 033.8

(51) Int. Cl. H01S 5/02257; H01S 5/02208; H01S 5/02255; H01S 5/02345; H01S 5/40

(52) U.S. Cl. CPC H01S 5/02257; H01S 5/02208; H01S 5/02255; H01S 5/02345; H01S 5/4031

(57) ABSTRACT

A laser diode device including at least one laser diode. The laser diode is an edge emitter. The laser diode device includes a housing having a transparent optical window, the transparent optical window being embodied as a first side wall of the housing. The housing is designed to shield the laser diode from an external environment of the laser diode device, in particular hermetically. The transparent optical window is designed to transmit at least one laser beam generated by the laser diode into the external environment. The laser diode is at least indirectly fastened to a base of the housing. The side walls of the housing and a housing cover situated opposite the housing base are produced from a multiplicity of wafers, in particular at least three.

### FIELD

The present invention relates to a laser diode device and a system having the laser diode device. In addition, the present invention pertains to a method for producing a laser diode device, a method for ascertaining a tightness of a housing of a laser diode device, and to a method for ascertaining an optical function of a first laser diode of a system.

### BACKGROUND INFORMATION

One skilled in the art is familiar with a laser diode device having an edge emitter as a laser diode and a housing within which the laser diode is situated.

An object of the present invention is to provide a laser diode device whose design is simplified and provides production-related advantages.

### SUMMARY

To achieve the object, according to the present invention, a laser diode device and a system including the laser diode device as recited are provided. In addition, a method for producing a laser diode device is provided. The present invention also includes a method for ascertaining a tightness of a housing of a laser diode device, and a method for ascertaining an optical function of a first laser diode of a system.

According to an example embodiment of the present invention, the laser diode device includes at least one laser diode, which is embodied as an edge emitter. In addition, the laser diode device had a housing including a transparent optical window, which is developed as a first side wall of the housing. The housing is designed to shield the laser diode from an external environment of the laser diode device. The transparent optical window is developed to transmit at least one laser beam generated by the laser diode into the external environment. The laser diode is at least indirectly fastened to a base of the housing. In edge emitters, the beam density is very high at the exit point of the laser beam, i.e., the chip edge. In the presence of harmful gaseous or solid substances in the environment, photochemical reactions with these materials can be triggered in the region of a high beam intensity, which lead to a destruction of the laser diodes. To avoid these reactions, the housing is particularly designed to hermetically seal the laser diode from an external environment of the laser diode device. The side walls of the housing and a housing cover situated opposite the housing base are developed from a multiplicity of wafers, especially at least three. This results in a housing which is developed as a wafer composite and formed by relatively few, easily connectable wafers. The laser diode is fastened inside the housing in such a way that a main emission direction of the laser diode is aligned essentially parallel to the base of the housing, especially essentially parallel to a first main extension plane of the base.

According to an example embodiment of the present invention, the first side wall of the housing is preferably developed as a transparent optical window made from a glass wafer, and a second side wall of the housing situated opposite the first side wall is made from a first silicon wafer. The further side walls, in particular a third and fourth side wall of the housing, and also a housing cover are made from a second silicon wafer.

The side walls preferably have a rectangular cross-section. The housing preferably has a cuboidal design. In this context, the housing has a first, second, third and fourth side wall as well as a housing base and a housing cover.

In addition, according to an example embodiment of the present invention, the laser diode device preferably includes a fastening element, which is situated separately from the housing and designed to fasten the laser diode within the housing in such a way that the at least one laser beam generated by the laser diode is transmitted directly into the external environment. In other words, the laser beam arrives at the optical transparent window without any prior deflection within the housing. The fastening element is preferably developed as a ceramic substrate. The laser diode is soldered to the electrically insulating ceramic substrate featuring a satisfactory thermal conductivity. Electric circuit traces and also electrical through-connections are applied on the ceramic. The laser diodes are electrically connected to the circuit traces by soldering and/or by wire bonds. The ceramic is in turn soldered to the housing base. As a result, the laser diode is connected to the ceramic substrate in a mechanical, electrical and thermal manner.

According to an example embodiment of the present invention, the housing base is preferably developed as a carrier substrate. This carrier substrate is preferably developed as a ceramic substrate. As an alternative, the carrier substrate is developed as a silicon substrate or a glass wafer substrate provided with electrical through-connections. This offers the advantage that the housing can still be developed as a wafer composite with few housing parts, whose production in silicon-glass technology is also simplified. The carrier substrate preferably has at least one first recess on an underside of the carrier substrate. If glass solder having a bonding temperature of more than 300° C. is used as a joining means of the carrier substrate to the remaining side walls of the housing, then the bonding process can be carried out only with the aid of a laser-assisted bonding process. The at least one, especially circumferential, first recess on the underside of the carrier substrate is provided to improve the coupling or receiving of the laser power.

According to an example embodiment of the present invention, the housing cover preferably has at least one second recess so that the housing cover is at least locally thinned. The thinned cover may be used to perform a tightness test of the housing and thus to carry out a test to ascertain to what extent the housing is actually hermetically sealed.

A further subject matter of the present invention is a system that includes two adjacently situated laser diode devices, as described above. According to an example embodiment of the present invention, the system additionally includes an optical detector such as a photodiode. A second one of the at least two adjacently situated laser diode devices has a mirror surface on an outer side of a second side wall of a second housing of the second laser diode device. The mirror surface is aligned relative to a first one of the at least two adjacently situated laser diode devices in such a way that at least one laser beam emitted by a first laser diode of the first laser diode device is deflected by the mirror surface in the direction of the optical detector. In particular, the outer side of the second sidewall is itself developed as a mirror surface. To this end, a recess on the outer side of the second side wall produced with the aid of KOH etching, for example, is particularly provided. The system preferably has a shared carrier substrate as a housing base on which the two adjacently situated laser diode devices are positioned. Here, too, the carrier substrate is preferably made from ceramic. Alternatively, the carrier substrate is made from a silicon wafer or a glass wafer having electrical through-connections. In a subregion between the first and the second laser diode device, the carrier substrate has an opening, which particularly is developed as a through hole. The mirror surface is aligned relative to the first one of the at least two adjacently situated laser diode devices in such a way that the at least one laser beam emitted by the laser diode of the first laser diode device is deflected by the mirror surface in the direction of the opening and the optical detectors situated in the beam path behind the opening. The positioning of the optical detector on a side facing the underside of the carrier device provides the advantage of making it possible to carry out both the electrical test of the wafer composite and the optical test of the laser diode from a shared side.

A further subject matter of the present invention is a method for producing a laser diode device. The produced laser diode device especially involves the above-described laser diode device. According to an example embodiment of the present invention, to begin with, a second silicon wafer is provided.

Next, a through hole is produced within the second silicon wafer with the aid of a first etching step. The through hole is produced especially with a rectangular cross-section. The first etching step is carried out with the aid of KOH etching or with the aid of trench etching in particular. In a further method step, a first silicon wafer is provided. The first and the second silicon wafer are then connected to one another in such a way that the first silicon wafer seals the produced through hole on an underside of the second silicon wafer. Next, a glass wafer is provided. In a following method step, the second silicon wafer and the glass wafer are connected to one another such that the glass wafer seals the produced through hole on a topside of the second silicon wafer. The wafer stack, including the first and second silicon wafer, and the glass wafer are separated along a separation plane. In other words, the wafer stack is cut or singularized along the separation plane. The separation plane extends along a main extension direction of the through hole so that the singularized housing parts include an individual side opening following the separation process. In a subsequent step, a carrier substrate is connected to the first silicon wafer, the second silicon wafer and the glass wafer in such a way that a laser diode embodied as an edge emitter and formed on an outer side of the carrier wafer is positioned within a housing defined by the carrier substrate, the first silicon wafer, the second silicon wafer, and the glass wafer. For this last method step, the singularized housing parts are preferably rotated by 90° so that the production method is able to be continued in a planar manner in a common plane.

According to an example embodiment of the present invention, a trench beam-stopper structure is preferably applied to a topside of the first silicon wafer. In particular, the trench beam-stopper structure is an etching which produces a beam-absorbent surface featuring a high roughness or column-type structures.

The connection between the carrier substrate and the first silicon wafer, the second silicon wafer and the glass wafer is preferably implemented in such a way that the housing is hermetically sealed. Glass solder is preferably used as a joining means for such a hermetic seal.

A multitude of laser diode devices is preferably produced. In this context, a multitude of through holes is produced in the second silicon wafer. The separating or singularizing of the wafer stack that takes place later is then implemented along the through holes, especially along separation planes that extend along the main extension directions of the through holes.

A further subject matter of the present invention is a method for ascertaining a tightness of a housing of a laser diode device. The above-described laser diode device, in which the housing cover has at least one second recess and is therefore at least locally thinned, is used for this purpose. According to an example embodiment of the present invention, to produce the second recess, overetching is preferably carried out when etching the through hole. Such overetching is able to be achieved with the aid of KOH etching, for example. In the test method, the carrier substrate is first connected to the first silicon wafer, the second silicon wafer and the glass wafer so that a defined internal pressure is generated within the housing defined by the carrier substrate, the first silicon wafer, the second silicon wafer and the glass wafer. The internal pressure has a pressure differential from the ambient pressure. In a subsequent step, a deformation of the housing cover is measured.

The tightness of the housing is then ascertained as a function of the measured deformation. It is especially ascertained in the process whether the produced housing is indeed hermetically sealed.

A further subject matter of the present invention is a method for ascertaining an optical function of a first laser diode of the above-described system, including the at least two adjacently situated laser diode devices and an optical detector. The optical function refers to a quality, especially a power, of the laser beam emitted by the first laser diode. According to an example embodiment of the present invention, in the method, at least one laser beam is initially emitted with the aid of a first laser diode situated within a first housing of a first laser diode device. Next, the emitted laser beam is deflected onto an optical detector with the aid of a mirror surface provided on an outer side of a second side wall of the second housing of a second laser diode device. The optical function of the first laser diode is then ascertained as a function of the deflected laser beam. More specifically, the optical function is ascertained as a function of an intensity distribution and/or a brightness and/or a wavelength of the deflected laser beam with the aid of the optical detector. The described method makes it possible to integrate the test of the optical function of the laser diode into the electro-optical test following the manufacturing process. No separate test device is required.

### BRIEF DESCRIPTION OF THE DRAWINGS

FIG. 1A, schematically and in a side view, shows a first sectional representation of a first exemplary embodiment of the laser diode device according to the present invention.

FIG. 1B, schematically and in a side view, shows a second sectional representation of the first embodiment of the laser diode device according to the present invention.

FIG. 1C, schematically and in a top view, shows a third sectional representation of the first embodiment of the laser diode device of the present invention.

FIG. 2, schematically and in a side view, shows a system which includes two adjacently situated laser diode devices, according to an example embodiment of the present invention.

FIG. 3A schematically shows method steps for producing a multiplicity of laser diode devices, according to an example embodiment of the present invention.

FIG. 3B schematically shows further method steps for producing a multiplicity of laser diode devices, according to an example embodiment of the present invention.

FIG. 3C schematically shows further method steps for producing a multiplicity of laser diode devices, according to an example embodiment of the present invention.

### DETAILED DESCRIPTION OF EXAMPLE EMBODIMENTS

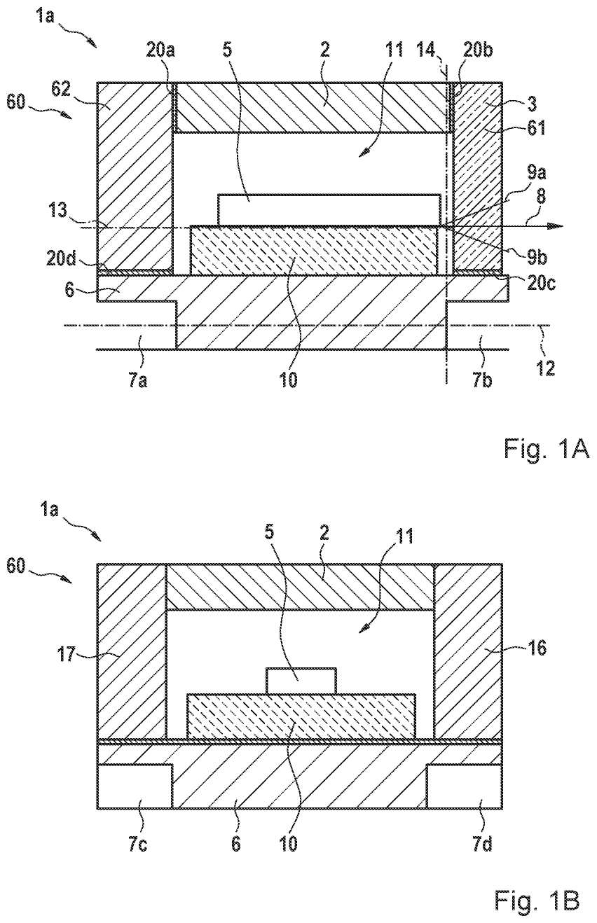

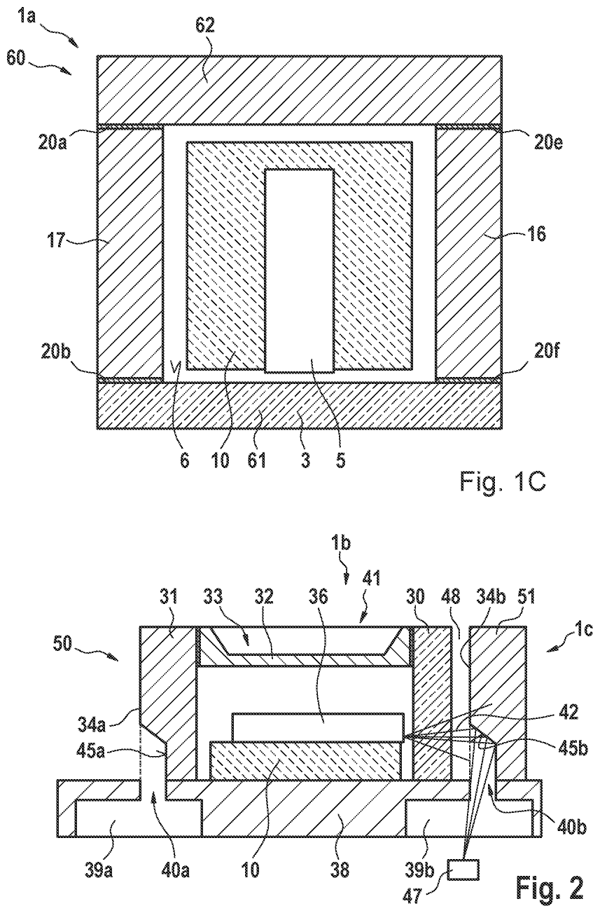

FIG. 1A schematically shows a first sectional representation of a first embodiment of laser diode device 1a in a side view. Laser diode device 1a includes a laser diode 5, which is embodied as an edge emitter. In addition, the laser diode device includes a housing 60 having a transparent optical window 3. Here, transparent optical window 3 is developed as a first side wall 61 of housing 60. Housing 60 is designed to shield laser diode 5 from an external environment of laser diode device 1a, in particular hermetically. Transparent optical window 3 is developed to transmit at least one laser beam 8 generated by laser diode 5 into the external environment. An angular range defined by beams 9a and 9b characterizes the region into which laser beam 8 is able to be emitted. The angular range defined by beams 9a and 9b, for instance, is a function of the wavelength of the laser beams. In this embodiment, laser diode 5 is indirectly fastened to a base 6 of housing 60 using a separate fastening element 10. First side wall 61 of housing 60 shown in this representation, second side wall 62 of housing 60, and a housing cover 2 situated opposite housing base 6 are formed by three wafers. Glass solder is used as a joining means 20a to 20d in this first embodiment.

In this embodiment, housing base 6 is developed as a carrier substrate. The carrier substrate is in turn made from silicon and has through-connections, which are not shown here. For a better coupling of the laser power in a laser-assisted bonding process, the carrier substrate is provided with a first circumferential recess 7a and 7b on an underside of the carrier substrate.

First side wall 61 of housing 60 in this embodiment is made from a glass wafer. Second side wall 62 of housing 60 is made from a first silicon wafer, and housing cover 2 is made from a second silicon wafer.

Side walls 61 and 62 have a rectangular cross-section, and housing 60 has a cuboidal development.

Fastening element 10, positioned separately from housing 60, is designed to fasten laser diode 5 in interior 11 of housing 60 in such a way that laser beam 8 generated by laser diode 5 is transmitted directly into the external environment. Fastening element 10 is developed as a ceramic substrate in this case. Electric circuit traces as well as electric through-connections, which are not shown here, are applied to the ceramic substrate. Laser diode 5 is electrically connected to the circuit traces by soldering and/or wire bonds. The ceramic then, in turn, is soldered to housing base 6. Thus, laser diode 5 is mechanically, electrically and thermally connected to fastening element 10.

In addition, laser diode 5 is fixed in place inside housing 60 in such a way that a main emission direction of laser diode 5 is in essence aligned parallel to a first main extension plane 12 of base 6.

FIG. 1B shows a second sectional representation of the first embodiment of laser diode device 1a, in a side view. The section was produced along sectional plane 14 in FIG. 1A. In addition, a third side wall 16 and a fourth side wall 17 of housing 60 can be seen. These side walls 16 and 17 are produced from the second silicon wafer. Additional recesses 7c and 7c can furthermore be seen in housing base 6.

FIG. 1C shows a top view of a third sectional representation of the first embodiment of laser diode device 1a. The section was implemented along sectional plane 14 in FIG. 1A. Also visible here are joining means 20e and 20f, which are developed in the form of glass solder in this instance.

FIG. 2, schematically in a side view, shows a system 50 which includes two adjacently situated laser diode devices 1b and 1c. However, for reasons of clarity, only first laser diode device 1b is shown in greater detail in this representation. System 50 additionally includes an optical detector 47. In contrast to laser diode device 1a shown in FIGS. 1A through 1C, first laser diode device 1b and also second laser diode device 1c are provided with a mirror surface 45a and 45b on outer sides 34a and 34b of the respective second side wall 31 and 51. Mirror surface 45b of second laser diode device 1c is aligned in such a way relative to first laser diode devices 1b that at least one laser beam 42 emitted by a first laser diode 36 of first laser diode device 1b is deflected by mirror surface 45b in the direction of optical detector 47. Optical detector 47 is set up to ascertain an optical function of first laser diode 36 as a function of deflected laser beam 42, especially as a function of an intensity distribution and/or a brightness and/or a wavelength. In this context, system 50 furthermore includes a shared carrier substrate of the at least two adjacently situated laser diode devices 1b and 1c, which serves as a housing base 38 of first laser diode device 1b. Here, too, the carrier substrate is provided with two circumferential recesses 39a and 39b on the underside of the carrier substrate. In a subregion 48 between the first 1b and second laser diode device 1c, the carrier substrate has an opening 40b, which is developed as a through hole. Mirror surface 45b is aligned in such a way relative to first laser diode device 1b that laser beam 42 emitted by laser diode 36 via optical transparent window 30 is deflected by mirror surface 45b in the direction of opening 40b and optical detector 47 situated in the beam path behind opening 40b.

In addition, in contrast to laser diode device 1a shown in FIGS. 1A through 1C, housing cover 32 of first laser diode device 1b has a second recess 33. In this case, second recess 33 has been produced by overetching. Such overetching can be achieved with the aid of KOH etching, for example. Thinned housing cover 32 is used to ascertain a tightness of housing 41 of first laser diode device 1b. In this context, when housing 41 is connected to the carrier wafer as a housing base 38, the gas pressure in the housing cavity is adjusted in such a way that a pressure differential from the ambient pressure is produced. The pressure differential leads to bulging of thinned housing cover 32. The tightness test is carried out by measuring/testing this bulging.

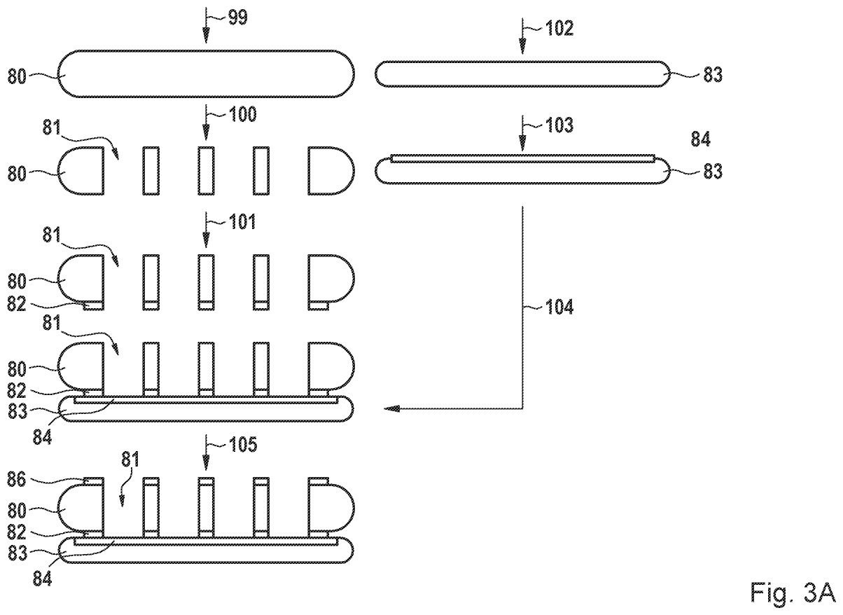

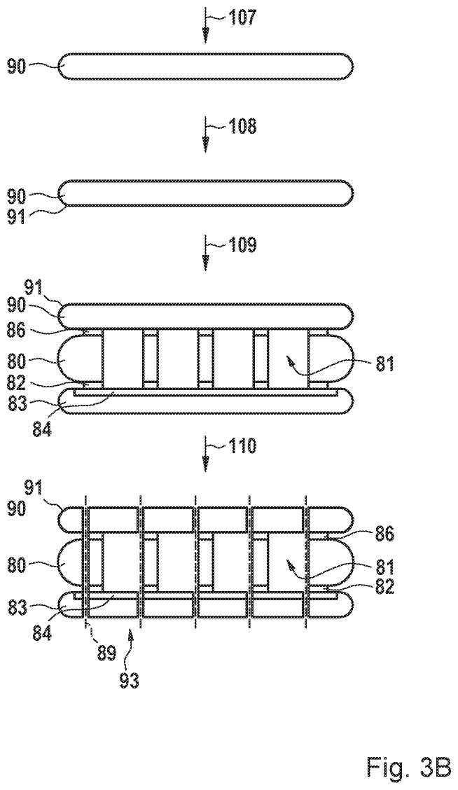

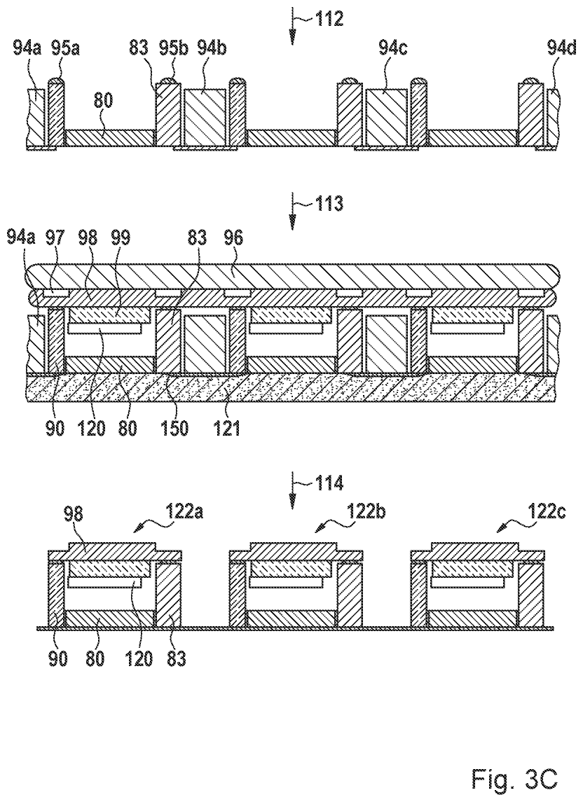

FIG. 3A schematically shows first partial steps of the method for producing a multiplicity of laser diode devices. In the process, a second silicon wafer 80 is initially provided in a first method step 99. In a following method step 100, through holes featuring a rectangular cross section are produced within the second silicon wafer with the aid of a first etching step. The first etching step in particular involves KOH etching or, alternatively, trench etching. In a subsequent method step 101, a joining means 82 is applied to an underside of second silicon wafer 80. Next, a first silicon wafer 83 is provided in a method step 102, and a trench beam-stopper structure 84 is applied to a topside of silicon wafer 83 in a following method step 103. Trench beam-stopper structure 84 particularly is an etching which generates a beam-absorbent surface characterized by great roughness or a column-type structure, for instance. In a following method step 104, first 83 and second silicon wafer 80 are connected to one another with the aid of joining means 82 such that first silicon wafer 83 seals produced through holes 81 on an underside of second silicon wafer 80. In a next method step, a joining means 86 is applied to the topside of the second silicon wafer.

FIG. 3B shows additional partial steps of the present method as a continuation of the method for producing a multiplicity of laser diode devices. In a method step 107 following method step 105, a glass wafer 90 is made available and provided with an anti-reflex coating 91 across the entire circumference. In a method step 109 following method step 108, second silicon wafer 80 and glass wafer 90 are joined to one another in such a way that glass wafer 90 seals through holes 81 produced on the topside of second silicon wafer 80. In a following method step 110, the wafer stack is separated along separation planes 89 and the individually produced housing parts or wafer stack elements are thereby separated from one another. The singularization of the housing parts takes place along separation planes 89, which extend along a main extension direction of through holes 81.

As a continuation of the method for producing a multiplicity of laser diode devices, FIG. 3C shows further partial steps of the method. In a method step 112 following method step 110, the housing parts are rotated by 90° and positioned in a tray 151 with openings 150 as a holding device 94a to 94d. In addition, glass solder is applied as a joining means 95a and 95b to a side surface of glass wafer 90 and to a side surface of first silicon wafer 83. In a method step 113 following method step 112, a pressure plate 96 is used to position a carrier substrate 98 is positioned relative to tray 151 with the housing parts, and carrier substrate 98 is connected to first silicon wafer 83, second silicon wafer 80 and glass wafer 90 in such a way that a laser diode 120 formed on an outer side of the carrier wafer and developed as an edge emitter is situated within a housing defined by carrier substrate 98, first silicon wafer 83, second silicon wafer 80, and glass wafer 90. Carrier substrate 98 and the housing parts are bonded to one another. In this exemplary embodiment, glass solder, whose bonding temperature lies essentially above 300° C., is used as a joining means. The bonding process may thus be carried out only with the aid of a laser-assisted bonding process. For the better coupling of the laser power, carrier substrate 98 is provided with first circumferential recesses 97 in this context. During the joining step, an elastic plate 121 bulges into openings 150 of tray 151 and thus generates a contact pressure at the housing parts. The laser diode is connected to carrier substrate 98 with the aid of a separate fastening element. In a method step 114 following method step 113, laser diode devices 122a to 122c are then also singularized.

1-16. (canceled)

17. A laser diode device, comprising:
at least one laser diode, the laser diode being an edge emitter; and
a housing having a transparent optical window, the transparent optical window being configured as a first side wall of the housing, and the housing being configured to shield hermetically, the laser diode from an external environment of the laser diode device, the transparent optical window being configured to transmit at least one laser beam generated by the laser diode into the external environment, the laser diode being at least indirectly fastened to a base of the housing, wherein side walls of the housing and a housing cover situated opposite the housing base are developed from at least three wafers.

18. The laser diode device as recited in claim 17, wherein the first side wall of the housing is produced from a glass wafer, and a second side wall of the housing situated opposite the first side wall is produced from a first silicon wafer, and a third side wall of the housing, a fourth side wall of the housing, and the housing cover are produced from a second silicon wafer.

19. The laser diode device as recited in claim 17, wherein the side walls have a rectangular cross-section.

20. The laser diode device as recited in claim 17, wherein the housing has a cuboidal configuration.

21. The laser diode device as recited in claim 17, wherein the laser diode device has a fastening element, which is situated separately from the housing, the fastening element being configured to fix the laser diode in position inside the housing in such a way that the at least one laser beam generated by the laser diode is transmitted directly into the external environment.

22. The laser diode device as recited in claim 17, wherein the housing base is a carrier substrate.

23. The laser diode device as recited in claim 22, wherein the carrier substrate is provided with at least one first circumferential recess on an underside of the carrier substrate.

24. The laser diode device as recited in claim 17, wherein the housing cover has at least one second recess.

25. A system, comprising:
at least two adjacently situated laser diode devices, each including:
at least one laser diode, the laser diode being an edge emitter, and
a housing having a transparent optical window, the transparent optical window being configured as a first side wall of the housing, and the housing being configured to shield hermetically, the laser diode from an external environment of the laser diode device, the transparent optical window being configured to transmit at least one laser beam generated by the laser diode into the external environment, the laser diode being at least indirectly fastened to a base of the housing, wherein side walls of the housing and a housing cover situated opposite the housing base are developed from at least three wafers and
an optical detector, a second one of the at least two adjacently situated laser diode devices being provided with a mirror surface on an outer side of a second side wall of the housing of the second laser diode device, and the mirror surface is aligned in such a way relative to a first one of the at least two adjacently situated laser diode devices that the at least one laser beam emitted by the laser diode of the first laser diode device is deflected by the mirror surface in a direction of the optical detector.

26. The system as recited in claim 25, wherein the system has as a housing base a shared carrier substrate of the at least two adjacently situated laser diode devices, and in a partial region between the first and the second laser diode device, the carrier substrate has an opening, the opening being a through hole, and the mirror surface is aligned in such a way relative to the first one of the at least two adjacently situated laser diode devices that the at least one laser beam emitted by the laser diode of the first laser diode of the first laser diode device is deflected by the mirror surface in a direction of the opening and the optical detector situated in a beam path behind the opening.

27. A method for producing a laser diode device, the method comprising the following steps:
providing a second silicon wafer;
producing a through hole having a rectangular cross-section, within the second silicon wafer using a first etching step, using KOH etching or trench etching;
providing a first silicon wafer;
connecting the first silicon wafer and second silicon wafer in such a way that the first silicon wafer seals the produced through hole on an underside of the second silicon wafer;
providing a glass wafer;
connecting the second silicon wafer and the glass wafer in such a way that the glass wafer seals the produced through hole on a topside of the second silicon wafer;
separating a wafer stack including the first silicon wafer, the second silicon wafer, and the glass wafer along a separation plane, the separation plane extending along a main extension direction of the through hole; and
connecting a carrier substrate to the first silicon wafer, the second silicon wafer, and the glass wafer in such a way that a laser diode developed on an outer side of the carrier substrate as an edge emitter is situated within a housing defined by the carrier substrate, the first silicon wafer, the second silicon wafer, and the glass wafer.

28. The method as recited in claim 27, wherein a trench beam-stopper structure is applied to a topside of the first silicon wafer.

29. The method as recited in claim 27, wherein the connecting of the carrier substrate to the first silicon wafer, the second silicon wafer, and the glass wafer, is carried out in such a way that the housing is hermetically sealed.

30. The method as recited in claim 27, wherein a multiplicity of through holes is produced in the second silicon wafer, and the separating of the wafer stack including separating the wafer stack along the through holes is implemented in such a way that a multiplicity of laser diode devices is produced.

31. A method for ascertaining a tightness of a housing of a laser diode device, the laser diode device including at least one laser diode, the laser diode being an edge emitter, and a housing having a transparent optical window, the transparent optical window being configured as a first side wall of the housing, and the housing being configured to shield hermetically, the laser diode from an external environment of the laser diode device, the transparent optical window being configured to transmit at least one laser beam generated by the laser diode into the external environment, the laser diode being at least indirectly fastened to a base of the housing, wherein side walls of the housing and a housing cover situated opposite the housing base are developed from at least three wafers, and wherein the housing cover has at least one second recess, the method comprising the following steps:
connecting a carrier substrate to the first silicon wafer, the second silicon wafer, and the glass wafer in such a way that a defined internal pressure is generated within the housing defined by the carrier substrate, the first silicon wafer, the second silicon wafer, and the glass wafer, the internal pressure having a pressure differential from the ambient pressure, and
measuring a deflection of the housing cover; and
ascertaining the tightness of the housing as a function of the measured deflection.

32. A method for ascertaining an optical function of a first laser diode of a system, wherein the method comprises the following steps:
emitting at least one laser beam using a first laser diode situated within a first housing of a first laser diode device;
deflecting the emitted laser beam onto an optical detector using a mirror surface provided on an outer side of a side wall of a second housing of a second laser diode device, the first and second laser diode devices being situated next to one another; and
ascertaining the optical function of the first laser diode as a function of an intensity distribution and/or a brightness and/or a wavelength, of the deflected laser beam, using the optical detector.
